(19) United States
(12) Patent Application Publication
(10) Pub. No.: US 2025/0019289 A1
(43) Pub. Date: Jan. 16, 2025

(54) TITANIA-SILICA GLASS BODY WITH HIGH QUALITY POLISHING CHARACTERISTICS

(71) Applicants: CORNING INCORPORATED, CORNING, NY (US); HOYA CORPORATION, Shinjuku-ku, Tokyo (JP)

(72) Inventors: Steven Bruce Dawes, Corning, NY (US); Douglas Hull Jennings, Corning, NY (US); Toshihiko Orihara, Shinjuku-ku (JP); Pushkar Tandon, Painted Post, NY (US)

(21) Appl. No.: 18/767,122

(22) Filed: Jul. 9, 2024

Related U.S. Application Data
(60) Provisional application No. 63/526,040, filed on Jul. 11, 2023.

(51) Int. Cl. C03B 19/06; C03B 25/02; C03C 3/076

(52) U.S. Cl. CPC C03B 19/063; C03B 25/025; C03C 3/076; C03B 2201/42; C03B 2215/02

(57) ABSTRACT

A method of forming a glass body, the method including pressing titania-doped silica soot to form a molded body, consolidating the molded body by heating the molded body, annealing the consolidated molded body, and polishing at least one surface of the annealed molded body to form the glass body. After the polishing, the at least one surface of the glass body has a waviness amplitude of about 0.60 nm or less in the spatial frequency range of 0.05 mm⁻¹ or more and 0.2 mm⁻¹ or less.

This application claims the benefit of priority under 35 U.S.C § 120 of U.S. Provisional Application Ser. No. 63/526,040 filed on Jul. 11, 2023, the content of which is relied upon and incorporated herein by reference in its entirety.

### FIELD

The present disclosure is directed to a titania-silica glass body with increased titania homogeneity such that the glass has high quality polishing characteristics, and in particular the present disclosure is directed to a titania-silica glass body with reduced surface waviness and increased flatness after a polishing process, along with methods of producing the glass body.

### BACKGROUND

Extreme ultraviolet (EUV) lithography uses optics to illuminate, project, and reduce pattern images to form integrated circuit patterns. The use of extreme ultraviolet radiation is beneficial in that smaller integrated circuit features can be achieved. The performance of an integrated circuit increases as the feature size decreases, since a decrease in feature size allows more circuitry to be put on a chip of a given size and reduces the power needed for operation. For example, the smaller the width of the circuitry, the more circuitry can be included on an integrated circuit.

Lithographic processes involve directing electromagnetic radiation onto a substrate that includes a layer (e.g., a chromium layer) etched with a particular integrated circuit pattern. The substrate with the integrated circuit pattern is typically referred to as a photomask. The image projected from the photomask (either via reflection or transmission) is directed onto a semiconductor wafer coated with a light sensitive photoresist material.

The substrate (with the integrated circuit pattern) is typically made from a low thermal expansion glass, such as silica-titania glass. One example of a suitable silica-titania glass is ultra-low expansion (ULE) glass, which, in some conventional methods, is formed by a flame hydrolysis process. Such a process involves the mixture of a silica precursor and a very pure titania precursor (e.g., octamethylcyclotetrasiloxane and titanium isopropoxide), which are delivered in vapor form to a flame to form SiO₂—TiO₂ soot particles. The soot particles melt in layers into a solid silica-titania optical blank. This is sometimes referred to as a “direct-to-glass” process. This conventional process produces large boules of the titania-silica glass.

However, this conventional process may cause the formation of striae in the glass body and ultimately the glass substrate. Striae are periodic inhomogeneities in the glass body that adversely affect properties of the glass body. Striae result in alternating thin layers of material with different coefficient of thermal expansion (CTE) values and, therefore, alternating planes of compression and tension between the layers.

In some cases, striae have been found to negatively impact the polish-ability of a glass plate removed or cut from the glass body. Polishing a glass plate that comprises striae results in unequal material removal and unacceptable surface waviness, which can present problems for stringent applications like EUV lithography elements. For example, it may create a mid-frequency surface structure that may cause image degradation in mirrors used in the projection systems for EUV lithography.

The inclusion of striae in the glass body also causes the glass body to have inhomogeneous thermal expansion, which can cause reflective optics made therefrom to have less than optimal thermal properties. The striae can make a glass body unsuitable for use in many optical transmission elements, such as lenses, windows, photomasks, or prisms.

Further, since the body substrate is polished prior to deposition of layers where the integrated circuit pattern is formed, polishing of glass having striae causes unacceptable waviness in the glass body, which may cause a problem in the accuracy of the integrated circuit pattern for EUV photolithography applications. In recent years, the required level of pattern position accuracy for a reflective mask fabricated from a glass body for EUV lithography has become particularly more stringent. When a transfer pattern of the reflective mask is transferred onto a wafer, if the position where the pattern is formed deviates from the desired position, the size of the circuit pattern formed on the wafer deviates, and a problem arises with the expected performance of the semiconductor device. The amount of deviation of the pattern formation position from the desired position is called overlay accuracy. As the circuit dimensions of semiconductor devices become smaller, smaller overlay accuracy is required. The next generation of EUV exposure equipment is expected to have high-power exposure of 500 watts or more, which makes demand of overlay accuracy more stringent.

Therefore, there is a need for a method of producing a titania-silica glass body that is suitable for EUV photolithography applications and that lacks striae. Moreover, there is a need for a glass body (e.g., a mask blank substrate) suitable for producing a reflective mask that can comply with the more stringent overlay accuracy requirements for higher power and smaller feature size of EUV exposure.

### SUMMARY

Aspects of the present disclosure provide a titania-silica glass body (and methods of making thereof) suitable for use in EUV photolithography applications. More specifically, the titania-silica glass body, and substrate produced therefrom, of the present disclosure both have a uniform and homogenous titania concentration, which therefore provides a uniform and homogenous CTE value across the glass. Therefore, the titania-silica glass body and substrate of the present disclosure both have reduced or no striae. Due to the reduced or lack of striae, the titania-silica glass body and substrate of the present disclosure have excellent polishing characteristics. When polished with the polishing processes, including the ones disclosed herein, the titania-silica glass body and substrate have very low surface waviness and flatness and, therefore, provides glass suitable for a mask blank substrate in EUV photolithography applications.

According to a first aspect, the present disclosure is directed to a method of forming a glass body, the method comprising pressing titania-doped silica soot to form a molded body, consolidating the molded body by heating the molded body, annealing the consolidated molded body, and polishing at least one surface of the annealed molded body to form the glass body. After the polishing, the at least one surface of the glass body has a waviness amplitude of about 0.60 nm or less in the spatial frequency range of 0.05 mm⁻¹ or more and 0.2 mm⁻¹ or less.

According to a second aspect of the present disclosure, the method of the first aspect, further comprising slicing the annealed molded body into at least one glass plate, the glass plate comprising a first main surface and a second main surface, and wherein the polishing at least one surface comprises polishing at least one of the first main surface and the second main surface to form the glass body.

According to a third aspect of the present disclosure, the method of the second aspect, wherein the polishing of the at least one surface of the glass plate comprises moving at least one of the glass plate and a polishing pad relative to each other, the polishing pad being formed of a foamed resin.

According to a fourth aspect of the present disclosure, the method of the first aspect, wherein the glass body comprises SiO₂—TiO₂ glass containing about 5 wt. % to about 10 wt. % TiO₂.

According to a fifth aspect of the present disclosure, the method of the fourth aspect, wherein a difference between a maximum concentration of TiO₂ and a minimum concentration of TiO₂ in the glass body is about 0.05 wt. % or less.

According to a sixth aspect of the present disclosure, the method of the fifth aspect, wherein pressing the titania-doped silica soot comprises pressing loose soot particles to form the molded body, the loose soot particles each have an average diameter from about 60 nm to about 140 nm.

According to a seventh aspect of the present disclosure, the method of the first aspect, wherein pressing the titania-doped silica soot comprises pressing loose soot particles to form the molded body, the loose soot particles each have an average diameter from about 60 nm to about 140 nm.

According to an eighth aspect of the present disclosure, the method of the seventh aspect, wherein the molded body is annealed at a maximum temperature from about 900° C. to about 1200° C.

According to a ninth aspect of the present disclosure, the method of first aspect, wherein the molded body is annealed at a maximum temperature from about 900° C. to about 1200° C.

According to a tenth aspect of the present disclosure, the method of the first aspect, wherein the polishing of the at least one surface of the glass plate comprises moving at least one of the glass plate and the polishing pad relative to each other, the polishing pad being formed of a foamed resin.

According to an eleventh aspect of the present disclosure, the method of the first aspect, wherein the glass body comprises SiO₂—TiO₂ glass and a difference between a maximum concentration of TiO₂ and a minimum concentration of TiO₂ in the glass body is about 0.05 wt. % or less.

According to a twelfth aspect of the present disclosure, a polished glass body is disclosed comprising a first surface having a waviness amplitude of about 0.60 nm or less in the spatial frequency range of 0.05 mm⁻¹ or more and 0.2 mm⁻¹ or less, wherein the polished glass body is a SiO₂—TiO₂ glass that contains about 5 wt. % to about 10 wt. % TiO₂.

According to a thirteenth aspect of the present disclosure, the polished glass body of the twelfth aspect, wherein a difference between a maximum concentration of TiO₂ and a minimum concentration of TiO₂ in the polished glass body is about 0.05 wt. % or less.

According to a fourteenth aspect of the present disclosure, the polished glass body of the thirteenth aspect, wherein the polished glass body is a mask blank substrate of a reflective mask for EUV lithography.

According to a fifteenth aspect of the present disclosure, the polished glass body of the twelfth aspect, wherein the polished glass body is a mask blank substrate of a reflective mask for EUV lithography.

According to a sixteenth aspect of the present disclosure, the polished glass body of the twelfth aspect, wherein the wherein the polished glass body comprises a root mean square roughness (Rms) of less than about 0.13 nm.

According to a seventeenth aspect of the present disclosure, the polished glass body of the sixteenth aspect, wherein the root mean square roughness (Rms) is less than about 0.12 nm.

According to an eighteenth aspect of the present disclosure, the polished glass body of the twelfth aspect, wherein the polished glass body comprises a flatness of about 0.1 μm or less.

According to a nineteenth aspect of the present disclosure, the polished glass body of the eighteenth aspect, wherein the flatness is about 0.05 μm or less.

According to a twentieth aspect of the present disclosure, the polished glass body of the twelfth aspect, wherein the waviness amplitude is about 0.45 nm or less.

### BRIEF DESCRIPTION OF THE DRAWINGS

FIG. 1 is a flowchart of a method of forming a glass substrate, according to embodiments disclosed herein;

FIG. 2 is a schematic illustration of a system to produce loose soot particles in the method of FIG. 1, according to the embodiments disclosed herein;

FIG. 3A is schematic illustration of an exemplary mold with soot particles deposited therein in the method of FIG. 1, according to embodiments disclosed herein;

FIG. 3B is schematic illustration of an exemplary molded body in the method of FIG. 1, according to embodiments disclosed herein;

FIG. 3C is schematic illustration of an exemplary consolidated molded body in the method of FIG. 1, according to embodiments disclosed herein;

FIG. 3D is schematic illustration of an exemplary glass body after the melting step in the method of FIG. 1, according to embodiments disclosed herein;

FIG. 3E is schematic illustration of an exemplary glass body after the annealing step in the method of FIG. 1, according to embodiments disclosed herein;

FIG. 4 is a schematic illustration of a glass substrate after the slicing and polishing step in the method of FIG. 1, according to embodiments disclosed herein;

FIG. 5 is a schematic sectional view of a substrate, according to the embodiments disclosed herein;

FIG. 6 is a schematic sectional view of a substrate with a multilayer reflective film, according to the embodiments disclosed herein;

FIG. 7 is a schematic sectional view of a reflective mask blank, according to the embodiments disclosed herein; and

FIG. 8 is a graph showing power spectrum analysis of the mask blank substrates of Example 1 and Comparative Example 1 on main surfaces of the substrates, where the transfer patterns are to be formed.

### DETAILED DISCLOSURE

As used herein, “ppm” means parts per million by weight.

As used herein, “atm” means atmosphere.

As used herein, “substrate” means a glass structure on which other materials are deposited or otherwise placed.

As used herein, “glass body” means a glass structure prior to cutting, or otherwise removing a portion thereof.

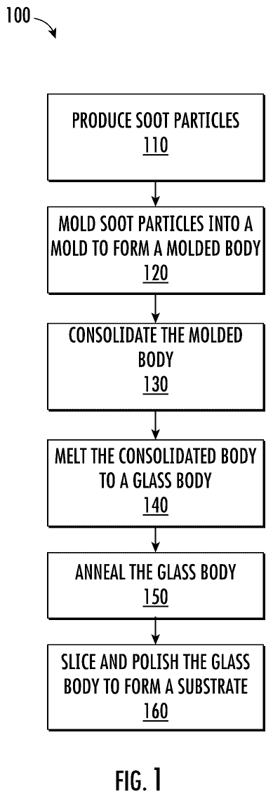

FIG. 1 depicts a process 100 to produce a titania glass substrate suitable for use in EUV lithography applications. As discussed further below, the produced glass has a uniform titania concentration and uniform CTE values across the substrate. Therefore, the substrate is suitable for use in EUV lithography applications. Step 110 of process 100 comprises the production of soot particles. More specifically, step 110 comprises forming the soot particles as loose soot particles and then collecting the loose soot particles. FIG. 2 depicts a schematic representation of a system 200 to produce the loose soot particles. Referring to FIG. 2, system 200 comprises a first reservoir 220 that houses a silica precursor 224 and a second reservoir 230 that houses a titania precursor 234. First reservoir 220 includes an inlet 222 for introduction of a carrier gas, such as nitrogen, at or near the base of the reservoir. The carrier gas forms a vaporous stream with the silica precursor 224. Similarly, second reservoir 230 includes an inlet 232 for introduction of a carrier gas, such as nitrogen, at or near the base of the reservoir. The carrier gas in second reservoir 230 forms a vaporous stream with the titania precursor 234.

The silica precursor 224 may comprise, for example, SiCl₄ and/or octamethylcyclotetrasiloxane (OMCTS). The titania precursor 234 may comprise, for example, TiCl₄, titanium isopropoxide (TPT), titanium tetraisopropoxide (TTIP), and/or tetraisopropyltitanate (TIPT).

Bypass streams of carrier gas are also introduced into system 200 at inlets 226 and 236 to prevent saturation of the vaporous silica stream and the vaporous titania stream. The vaporous silica stream then passes through distribution system 242 to manifold 248, and the vaporous titania stream passes through distribution system 244 to manifold 248.

The silica and titania vaporous streams then mix in manifold 248 to form a mixture of the two streams. As further shown in FIG. 2, the mixture of the two streams flows to furnace 250. More specifically, the mixture of the two streams passes through fume lines 252 to burners 254 mounted in an upper portion of furnace 250. The two streams are further joined with a fuel/oxygen mixture at burners 254 to combust and oxidize the mixture. The fuel may be natural gas. The oxidation and combustion of the mixture forms loose soot particles 260, which are cooled and directed into collection chamber 264. Soot particles 260 comprise silicon dioxide and titanium dioxide. More specifically, the silicon dioxide and titanium dioxide in the particles mix at the atomic level to form Si—O—Ti bonds.

In some embodiments, soot particles 260 are directed upward through a tube 270 rather than downward into collection chamber 264. Tube 270 may be a quartz tube, which carries soot particles 260 in a vaporous stream to one or more filter bags 272. The soot particles 260 are removed from the vaporous stream by the filter bags 272 and are then deposited into one or more collection chambers 264′. For example, the soot particles 260 fall downward from filter bags 272 and into collection chambers 264′. A pulse of N₂ may periodically be applied to filter bags 272 to prevent the excess accumulation of soot particles 260 on the bags. In some embodiments, collection chambers 264′ are stainless steel hoppers. The soot particles 260 can then be further collected from collection chambers 264′ and deposited into barrels, where soot particles 260 may be stored until further use.

The produced soot particles 260 are spherical in shape with substantially uniform distributions of SiO₂ and TiO₂ within the particles. In addition to SiO₂ and TiO₂, the composition of soot particles 260 may also comprise CO and CO₂, which may be incorporated into the particles due to the fuel at burners 254. The size of each soot particle 260 may vary depending on the conditions of burners 254, but in general, soot particles 260 have an average diameter of about 60 nm to about 140 nm, or about 80 nm to about 120 nm, or about 100 nm.

Soot particles 260 may cool to about 200° C. or less, or about 175° C. or less, or about 150° C. or less, or about 125° C. or less, or about 100° C. or less, or about 75° C. or less, or about 50° C. or less, or about 25° C. or less, or about 20° C. or less before reaching collection chambers 264, 264′.

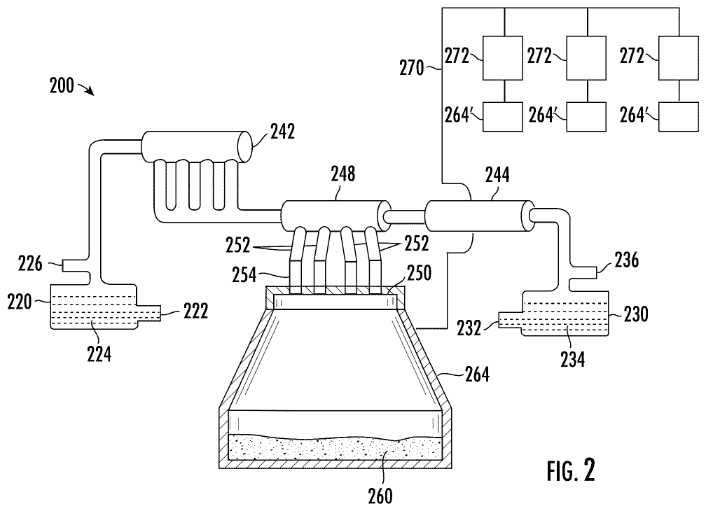

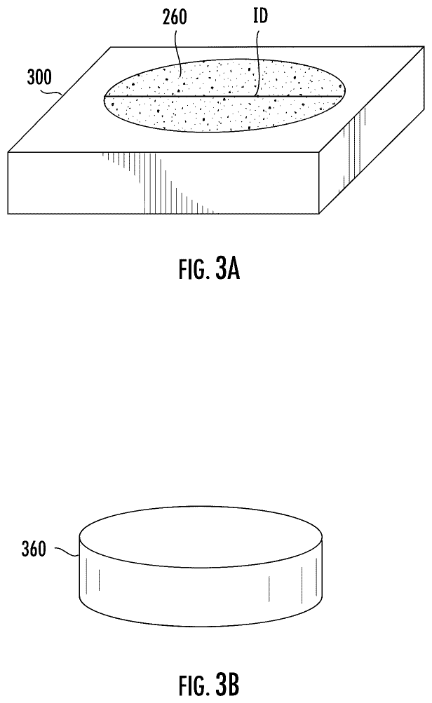

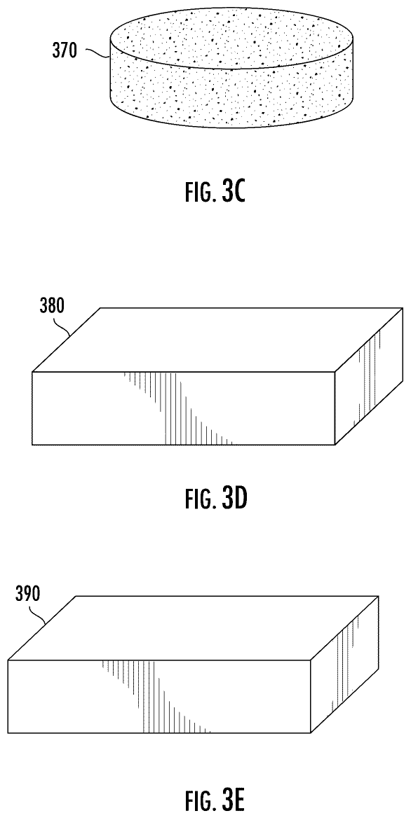

With reference again to FIG. 1, at step 120 of process 100, soot particles 60 are deposited into a mold. For example, soot particles 260 may be manually scooped from collection chambers 264, 264′ and loaded into the mold. FIG. 3A shows an exemplary embodiment of a mold 300 with soot particles 260 deposited therein. Soot particles 260 may be deposited into mold 300 at room temperature (˜20° C.). In some embodiments, mold 300 is comprised of graphite. However, it is also contemplated that mold 300 may comprise other materials as are well-known in the art. Mold 300 may have various sizes. In some embodiments, mold 300 has an inner diameter (ID) of about 300 mm, or about 250 mm, or about 200 mm.

Next, soot particles 260 are pressed within mold 300. More specifically, mold 300 (with the soot particles deposited therein) are moved to a pressing apparatus, which comprises a pressing plate that presses on soot particles 260 and applies pressure thereto until soot particles 260 have a density in a range from about 0.50 g/cm³ to about 1.20 g/cm³, or about 0.60 g/cm³ to about 1.10 g/cm³, or about 0.80 g/cm³ to about 1.00 g/cm³, or about 0.90 g/cm³ to about 0.95 g/cm³. The pressing plate may press on soot particles 260 at a constant pressing rate followed by a fixed press on soot particles for a predetermined amount of time.

After the pressing process by the pressing apparatus, soot particles 260 now form a molded body 360 (FIG. 3B). In order to remove molded body 360 from mold 300, the components are heated. The components may be heated to a temperature of about 1000° C. or higher, or about 1015° C. or higher, or about 1030° C. or higher, or about 1045° C. or higher, or about 1060° C. or higher to induce a small amount of sintering, which produces a very small size reduction in molded body 360, allowing molded body 360 to be removed from mold 300. In some embodiments, molded body 360 is heated in a demold furnace in a nitrogen atmosphere to prevent combustion of the graphite mold.

As shown in FIG. 3B, molded body 360 may have the size and shape of the interior portion of mold 300. In some embodiments, such as the embodiment shown in FIG. 3B, molded body 360 is cylindrical in shape. Molded body 360 may be referred to as a “soot blank.”

Referring again to process 100 of FIG. 1, molded body 360 is subjected to a consolidation step at step 130. For this step, molded body 360 may be placed into a consolidation furnace. First, the consolidation furnace may heat molded body 360 at a temperature of about 100° C. to about 1000° C., or about 200° C. to about 900° C., or about 300° C. to about 800° C., or about 400° C. to about 700° C. This heating of molded body 360 may be in an inert environment in the presence of an inert gas. Furthermore, this heating of molded body 360 may be accomplished to burn out any residual carbon in the soot.

Next, the environment within the consolidation furnace may be changed to steam by flowing steam into the furnace at a constant rate to achieve a pressure within the furnace of up to about 10 atm, or about 0.1 atm to about 10 atm, or about 0.5 atm to about 5.0 atm, or about 0.7 to about 2.5 atm, or about 0.9 to about 1.3 atm. Furthermore, the consolidation furnace is heated to a temperature of about 900° C. to about 1500° C., or about 1000° C. to about 1400° C., or about 1030° C. to about 1300° C., or about 1050° C. to about 1200° C. during the flowing of the steam. Once a predetermined constant pressure has been achieved, the molded body 360 is then slowly heated to a temperature within the range of about 1100° C. to about 1800° C., or about 1200° C. to about 1700° C., or about 1250° C. to about 1600° C., or about 1100° C. to about 1150° C., or about 1100° C. to about 1200° C., or about 1100° C. to about 1250° C., or about 1600° C. to about 1800° C., or about 1700° C. to about 1800° C. This slow heating of the molded body 360 may cause the collapse of any gas inclusions within the molded body.

The duration of the steam treatment in the consolidation furnace may be about 0.5 hours or greater, or about 1 hour or greater, or about 2 hours or greater, or about 5 hours or greater. This allows the molded body 360 to densify into a consolidated molded body 370, as shown in FIG. 3C. In exemplary embodiments, the consolidated molded body 370 is a dense, opaque substrate. The duration of the steam treatment in the consolidation furnace may be about 10 hours or less, or about 8 hours or less.

In step 140, the consolidated molded body 370 is melted in a furnace to produce a glass body 380 (as shown in FIG. 3D). Step 140 comprises placing consolidated molded body 370 in a mold and heating the body so that the heated glass flows and fills the interior of the mold. In some embodiments, the heating step is performed in an N₂ atmosphere. The glass body 380 is then cooled after the melting step. The cooled glass body 380 is no longer opaque and, instead, is now a transparent glass. However, an outer surface of the glass body 380 may have a discoloration where the glass body 380 contacted the mold. This discoloration can be removed via machining or cutting. In the embodiment of FIG. 3D, the consolidated molded body 370 was melted in a rectangular mold so that the glass body 380 is a rectangular cuboid.

After the melting step, in step 150, the glass body 380 is then annealed to relax any internal stress in the substrate. Relaxed internal stress allows for better quality cutting and machining of the glass body 380, such as slicing the glass body 380 into a plurality of slices. In some embodiments, the glass body 380 is annealed for a duration of about 100 hours or more, or about 200 hours or more, or about 250 hours or more. The glass body 380 is annealed for a duration of about 1000 hours or less, or about 500 hours or less. The maximum annealing temperature may be from about 900° C. to about 1200° C., or about 900° C. to about 1100° C., or about 900° C. to about 1000° C. FIG. 3E shows an exemplary glass body 390 after the annealing step.

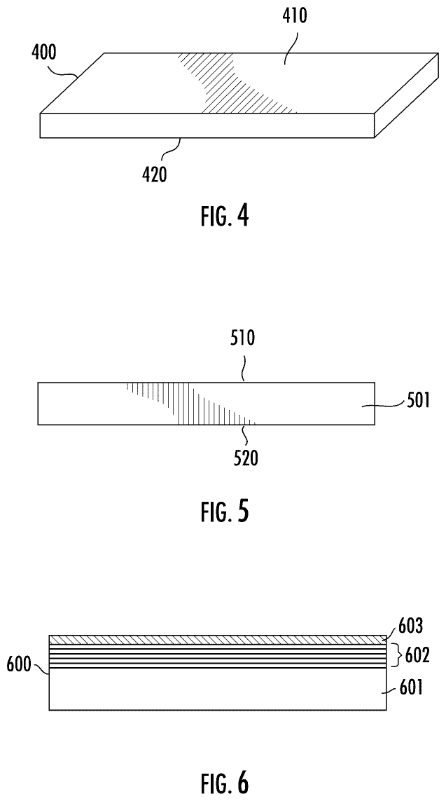

After the annealing step, the glass body 390 may be sliced and polished to form a glass body 400, as shown in step 160 of FIG. 1. Glass body 400 forms a substrate once one or more materials (such as the film layers disclosed below) are deposited or otherwise placed on the glass body. FIG. 4 shows an exemplary glass body 400 with a first main surface 410 and an opposing second main surface 420. At this point, the glass body 400 is a titania-silica glass body with superior properties. The glass body 400 has a composition comprising about 5 wt. % to about 10 wt. % TiO₂ and about 90 wt. % to about 95 wt. % SiO₂. In some embodiments, the glass body 400 has a TiO₂ concentration from about 5 wt. % to about 10 wt. %, or from about 6 wt. % to about 8 wt. %, or from about 7 wt. % to about 8 wt. %. Furthermore, the glass body 400 has a homogeneous TiO₂ concentration through the body. Thus, a concentration of TiO₂ may be substantially uniform throughout the entire glass body 400. In embodiments, a difference between a maximum TiO₂ concentration and a minimum concentration of TiO₂ in the glass body 400 (and the glass body 390) may be about 0.050 wt. % or less, or about 0.020 wt. % or less, or about 0.010 wt. % or less, or about 0.007 wt. % or less, or about 0.004 wt. % or less, or about 0.002 wt. % or less. Such a homogenous TiO₂ concentration, along with the polishing process disclosed below, allows the glass body 400 to be polished to a very low surface waviness.

The concentration of TiO₂ in glass body 400 is determined using a microprobe analyzer. In particular, the glass samples for analysis with the microprobe analyzer are first prepared as polished cross-sections and a conductive carbon coating is evaporated on the polished surface. Electron probe micro-analyzer (EPMA) analyses are performed on the glass samples using a JEOL 8500F Hyperprobe (2008) electron microprobe analyzer. This microprobe analyzer quantifies measurements from a titanium K-alpha x-ray line using a pentaerythritol (PET) diffracting element in a wavelength dispersive spectrometer. A micro-TiO₂, rutile form standard in the 53 minerals standard block (Serial No. 99-143 from Structure Probe Inc., West Chester Pa) is used to peak the spectrometer position and calibrate the number of Ti K-alpha x-ray measurements at a known electron beam current and time. Typical beam parameters used for analyses are 15 keV accelerating potential at 50-100 nA beam current with on-peak count times ranging from 10-30 seconds. Beam current and count times can be changed to greater or lesser values depending on the titanium concentration and/or precision needed for the analyses. Line scan or point analyses are performed on the glass samples using either a focused or defocused beam where the beam spot size is determined based upon the size of the feature of interest (e.g. focused or 1 um spot for striae, defocused 10-20 um spot for homogeneity) and stepped across the region of interest at a step size dictated by the size of the feature of interest. Results are reported as weight percent oxide assuming stoichiometry.

The glass body 400 (and the glass body 390) may additionally contain a halogen (such as F or Cl) or OH within the range that satisfies the desired performance.

Furthermore, the glass body 400 (and the glass body 390) has ultralow expansion properties that make the glass body 400 suitable for use with EUV lithography applications. In embodiments, the glass body 400 (and the glass body 390) comprises a CTE value at 20° C. in a range from −45 ppb/K to +20 ppb/K, or a CTE value at 20° C. of −45 ppb/K, −40 ppb/K, −35 ppb/K, −30 ppb/K, −25 ppb/K, −20 ppb/K, −15 ppb/K, −10 ppb/K, −5 ppb/K, 0 ppb/K, +5 ppb/K, +10 ppb/K, +15 ppb/K, +20 ppb/K, or within any range bounded by any two of those values (e.g., −40 ppb/K to −25 ppb/K, −15 ppb/K to +15 ppb/K, etc.). Such ultralow CTE values at room temperature allow the shape of the glass body 400, whether formed into a mirror or a photomask (such as a reflective mask), to remain substantially constant upon heating, during the EUV lithography process.

In embodiments, the glass body 400 (and the glass body 390) comprises a crossover temperature (Tzc) in a range from about 10° C. to about 50° C., or from about 20° C. to about 38° C., or from about 22° C. to about 38° C. In embodiments, the glass body 400 comprises a crossover temperature (Tzc) of about 10° C., or about 15° C., or about 20° C., or about 25° C., or about 30° C., or about 35° C., or about 40° C., or about 45° C., or about 50° C., or within any range bounded by any two of those values (e.g., 15° C. to 40° C., 20° C. to 45° C., etc.). The crossover temperature is the temperature at which the CTE of the glass body 400 is exactly zero. When the glass body 400 is utilized in EUV lithography applications, the crossover temperature is ideally within the temperatures that the glass body is expected to experience, in order to minimize thermal expansion of the glass substrate during the lithography process. Designers of EUV lithography systems calculate an optimum crossover temperature for each glass body 400 in the system, based on the thermal load, size, and heat removal rates afforded by the system. The crossover temperature of the glass body 400 is additionally determined by the technique disclosed in U.S. Pat. No. 10,458,936, which is incorporated by reference herein.

Furthermore, the glass body 400 (the glass body 390) has a slope of CTE at 20° C. in a range from about 1.20 ppb/K² to about 1.75 ppb/K². In embodiments, the glass body 400 has a slope of CTE at 20° C. of about 1.20 ppb/K², or about 1.25 ppb/K², or about 1.30 ppb/K², or about 1.35 ppb/K², or about 1.40 ppb/K², or about 1.45 ppb/K², or about 1.50 ppb/K², or about 1.55 ppb/K², or about 1.60 ppb/K², or about 1.65 ppb/K², or about 1.70 ppb/K², or about 1.75 ppb/K², or within any range bounded by any two of those values (e.g., in a range from 1.30 ppb/K² to 1.65 ppb/K², in a range from 1.35 ppb/K² to 1.75 ppb/K², etc.). The slope of CTE of the glass body 400 is the rate of change of the CTE of the glass body 400 as a function of the temperature of the glass body 400. When the glass body 400 is utilized in EUV lithography applications, the slope of CTE is ideally minimized so that the glass body experiences minimal thermal expansion caused by fluctuations in the temperature of the glass body during the EUV lithography process. CTE slope is additionally measured by the technique disclosed in aforementioned U.S. Pat. No. 10,458,936.

The glass body 400 (and the glass body 390) may be a homogeneous glass with reduced or no striae. As noted above, striae are periodic inhomogeneities in glass that can adversely affect properties of glass. More specifically, striae are formed by alternating thin layers of material in glass with different CTE values. Process 100, as discussed above, forms glass substrates with homogeneous CTE values throughout and, therefore, forms glass substrates with reduced or no striae.

Due to the low striae content in the glass body 390, the resulting glass body 400 can be polished to a very low surface waviness. As also discussed above, polishing glass with striae results in unequal removal of the glass material. For example, a first layer of glass material with a first CTE value may polish at a faster rate than a second layer of glass material with a second CTE value. In this example, the different CTE values in the layers of glass material be the result of striae in the glass. Furthermore, in this example, the first layer may be removed from the glass at a faster rate than the second layer is removed from the glass, even when both layers are exposed to the same polishing process. Therefore, in this example, the glass will have an unequal removal of material when polishing the first and second layers. Such unequal removal of material results in suboptimal surface waviness after the polishing process. In contrast to this example, the glass body 400 (and glass body 390) is produced to have homogeneous CTE values throughout the glass body. Therefore, the glass body 400 (and glass body 390) may be polished to have a superior surface waviness.

As discussed above, step 160 of process 100 comprises slicing the glass body 390 into a plurality of glass plates and polishing each glass plate to form a glass substrate. In some embodiments, the glass body 390 is sliced into about 6 or 8 glass plates. The glass plate may also be referred to herein as a “slice” or a “glass body” or a “glass patter blank”. In some examples, glass body 400 is a glass plate sliced from glass body 390. Polishing each glass plate may comprise magnetorheological finishing (MRF), chemical mechanical polishing (CMP), gas cluster ion beam etching (GCIB), dry chemical planarization (DCP) using local plasma etching, and/or the below disclosed polishing processes. MRF is a local treatment method in which abrasive grains contained in a magnetic fluid are brought into contact with a glass plate at a high speed. CMP is a local treatment method in which a small-diameter polishing pad and a polishing agent (which contain abrasive grains of colloidal silica or the like) are used. GCIP is a local treatment method in which a reactive material in gaseous form at normal temperature and pressure (source gas) is adiabatically expanded in a vacuum device and ejected to generate gas cluster. Then gas cluster ions, which are generated through ionization by electron irradiation, are accelerated in a high electric field into a gas cluster ion beam, and the gas cluster ion beam is radiated to the glass plate to be etched. DCP is a local treatment method in which plasma etching is locally performed with the plasma etching amount being controlled.

By using the method of producing a glass substrate (as disclosed above with reference to process 100), the glass substrate can be polished to a very low surface roughness. After the polishing step 160 of process 100 (as shown in FIG. 1), the glass substrate may have a low surface roughness, as discussed below.

Furthermore, with the method of producing the glass substrate (as disclosed above with reference to process 100), the glass substrate may have superior flatness. More specifically, glass body 400 (and the substrate produced therefrom) may have a flatness of about 0.30 microns or less, or about 0.25 microns or less, or about 0.20 microns or less, as measured with a wavelength shift interferometer using a laser wavelength modulation in a 132 mm×132 mm region of a surface of the glass body 400. Therefore, the glass body 400 of the present disclosure can be used as an optical blank for producing many optical elements, such as, for example, lenses, windows, photomasks (such as reflective masks), or prisms.

FIG. 5 shows a schematic sectional view of an exemplary mask blank substrate 501 produced according to the embodiments disclosed herein. As noted above, the glass body 400 can be used to form a mask blank substrate (such as substrate 501). The exemplary mask blank substrate 501 is a plate-like glass substrate in a rectangular shape, and has two opposed main surfaces 510, 520 along with end surfaces. Thus, mask blank substrate 501 is similar in shape to the glass body 400 described above. The two opposed main surfaces 510, 520 are an upper surface and a lower surface, respectively, of the mask blank substrate 501 and are formed to be opposed to each other. Further, at least one of the two opposed main surfaces 510, 520 is a main surface on which a transfer pattern is to be formed.

At least one of the main surfaces 510, 520 of the mask blank substrate 501 on the side where the transfer pattern is to be formed, a multilayer reflective film, a protective film, and an absorber film are formed. Thus, this surface of the mask blank substrate 501 (on the side where the transfer pattern is to be formed) must be even with low surface roughness and high flatness in order to form uniform and consistent film layers on this surface.

Hereafter, amplitude, which is a parameter indicating the surface profile of the main surface of the glass body or substrate, and other parameters including surface roughness (Rms) and flatness, are explained.

The periodic unevenness of the main surface of a glass body or substrate may be represented by amplitude at a predetermined spatial frequency or over a range of spatial frequencies. As such, unevenness may be calculated over a range of periods of interest. One exemplary method of measuring the waviness of a surface may be obtained by using a Fourier transform of the heights of the main surface of a glass body or substrate over a range of periodic intervals, e.g. spatial frequencies. This exemplary measurement may be obtained using a surface profile analysis apparatus. This type of analysis for a surface profile using Fourier transform is referred to as “power spectrum analysis” and is used as an example herein to calculate the waviness of a surface. The power spectrum analysis with the Fourier transform transforms measured data of the unevenness (i.e., minute profile of the main surface of the glass body or substrate) into a sum of waves over a range of predetermined spatial frequencies. That is, the surface profile of the glass body or substrate is divided into groups of predetermined spatial frequencies.

Such power spectrum analysis may convert the fine surface profile of the glass body 400 (and of, for example, mask blank substrate 501) into a numerical form. When a profile data xₖ is an amplitude in a specific “y” coordinate on the surface profile, Fourier transform X₁ is given by Expression (1) below. Thus, the amplitude spectra for each spatial frequency component can be obtained for the multiple frequencies included in the profile.

$$\begin{matrix}{X}_{l} = {\sum }_{k = 0}^{N - 1} {x}_{k} exp ( - j 2 π \frac{lk}{N} ) \\ l = 0 , 1 , … , N - 1\end{matrix} \qquad ( 1 )$$

In Expression (1), “k” (=0, 1, 2, . . . , N−1) is a profile data for performing Fourier transform, and “N” is number of data.

A shape of a main surface of glass body 400 on which the transfer pattern is formed has an amplitude of about 0.6 nm or less in a range of spatial frequencies from 0.05 mm⁻¹ to 0.2 mm⁻¹. The amplitude in the range of the spatial frequencies from 0.05 mm⁻¹ to 0.2 mm⁻¹ can be about 0.45 nm or less. The amplitude in the range of the spatial frequencies from 0.05 mm⁻¹ to 0.2 mm⁻¹ can be about 0.35 nm or less.

A surface profile analysis apparatus can be used for measuring a surface state of a glass body or substrate. According to the embodiments disclosed herein, the UltraFlat™ 200M (made by Corning Tropel®) is the surface profile analysis apparatus used to determine the surface state of the glass body or substrate. The measurement area of the glass body or substrate is an inner area of a square with a side of 142 mm aligned to the center of the glass body or substrate as a reference. Power spectrum analysis is then performed using Metro Pro ver. 8.0.1 (Zygo Corporation).

Because the glass body 400 of the present disclosure can be manufactured to control the amplitude of the main surface of the glass body as described above, a pattern can be transferred to the glass body while still satisfying the requirement of overlay accuracy. More specifically, even when a reflective mask is fabricated using a reflective mask blank (such as mask blank substrate 501) and an exposure transfer is performed to a resist film on a semiconductor substrate using a next-generation high-power exposure device, a pattern can be transferred to the substrate while still satisfying the requirement of overlay accuracy.

Root means square (Rms), which is a typical index of the surface roughness of a glass body or substrate, is a root mean square roughness, and is a square root of a mean value of squares of deviations from an average line to a measurement curve. Specifically, Rms is expressed by Expression (2) below.

$$Rms = \sqrt{\frac{1}{L} {\int }_{0}^{L} {Z}^{2} ( x ) dx} \qquad ( 2 )$$

In Expression (2), “L” is a reference length and “Z” is a height from the average line to the measurement curve.

Rms, as disclosed herein, is obtained through measurement of a region of 1 μm×1 μm of the main surface of the glass body or substrate using an atomic force microscope.

Further, the root mean square roughness (Rms) of glass body 400 is less than about 0.13 nm, more preferably about 0.12 nm or less, and further preferably about 0.10 nm or less. The root mean square roughness, as used herein, is a value in a case of calculation from the result of measurement of a region inside a square of 1 μm×1 μm on the main surface of the glass body 400 using an atomic force microscope.

The first main surface of the glass body 400 (the surface on which the transfer pattern is formed) may have a surface roughness (Ra) of about 0.50 nm or less, or about 0.45 nm or less, or about 0.40 nm or less, or about 0.35 nm or less, or about 0.30 nm or less, or about 0.25 nm or less, or about 0.20 nm or less, wherein the surface roughness (Ra) is the arithmetic average of the absolute value of the profile height deviations from a mean height. In some embodiments, the surface roughness (Ra) is in a range from about 0.20 nm to about 0.50 nm, or about 0.25 nm to about 0.45 nm, or about 0.30 nm to about 0.40 nm. The surface roughness (Ra) was measured using standard atomic force microscopy (AFM) techniques, as is known in the art.

In the glass body 400, according to embodiments disclosed herein, a first main surface of the glass body on the side on which the transfer patter is formed is a surface-treated surface so as to be highly flat from the viewpoint of obtaining pattern transfer accuracy and positional accuracy. In the case of a glass body 400 used for EUV exposure (such as the mask blank substrate 501), in a region inside of a square of 132 mm×132 mm of the first main surface of the glass body 400 on the side on which the transfer pattern is formed, the flatness is preferably about 0.1 μm or less, more preferably about 0.05 μm or less, and particularly preferably about 0.03 μm or less. In a region inside of a square of 142 mm×142 mm of a second main surface of the glass body 400, which is a main surface fixed to the exposure apparatus by an electrostatic chuck, on the side opposite to the side on which the transfer pattern is formed, the flatness is preferably about 0.1 μm or less, more preferably about 0.05 μm or less, and particularly preferably about 0.03 μm or less. As used herein, flatness is a value that represents warpage (amount of deformation) of a surface of a glass body or substrate with the total indicated reading (TIR). When a flat surface determined according to the least squares method based on the surface of the glass body or substrate is used as a focal plane, this value is a relative value of the height difference between the highest location of the surface of the glass body or substrate above this focal plane and the lowest location of the surface of the glass body or substrate below this focal plane. Measurement of the flatness of the glass body or substrate is carried out using a flatness measuring apparatus (Corning Tropel® UltraFlat™ 200).

### Manufacturing Method of Substrate

As discussed above with reference to process 100, the substrate produced from glass body 400 may be manufactured by slicing a glass body and carrying out the polishing of step 160. The polishing of step 160 may comprise a rough polishing process, a precision polishing process, an ultra-precision polishing process, a local treatment process and a finishing polishing process. In some embodiments, the rough polishing process, the precision polishing process, the ultra-precision polishing process, and the finishing polishing process use a double side polisher. The double side polisher may be the polisher disclosed in U.S. Pat. No. 9,778,209 B, which is incorporated by reference herein.

The material and the particle size of the polishing agent for each above-disclosed polishing process may be appropriately selected depending on the substrate material and target flatness. Exemplary polishing agents include cerium oxide, zirconium oxide, silica, and colloidal silica. Particle size of polishing agents is from tens of micrometers to several micrometers.

The rough polishing process is a step of performing polishing using abrasive grains that have a relatively large mean particle size from about 1 μm to about 3 μm. The purpose of the rough polishing process is to remove flaws on a main surface of the substrate (the glass plate) formed in a grinding step and to maintain flatness after such a grinding step. A material of the abrasive grains is appropriately selected depending on the material of the substrate (the glass plate). It is preferred that the polishing pad used in the rough polishing process is a hard polisher from the viewpoint of maintaining the flatness.

The precision polishing process is a step of performing polishing using abrasive grains that have a relatively small mean particle size of about 1 μm or less (for example, from about 10 nm to about 1 μm). The purpose of the precision polishing process is to preform mirror polishing of the substrate (the glass plate) so that the substrate does not have any surface defects (e.g., such that the substrate does not have any flaws). Similar to the rough polishing process, a material of the abrasive grains is appropriately selected depending on the material of the substrate (the glass plate). From the viewpoint of being able to obtain a smooth main surface of the substrate (the glass plate) with a small mean particle size, cerium oxide is preferred. It is preferred that the polishing pad used in the precision polishing process is a soft or ultra-soft polisher from the viewpoint of mirror polishing.

The ultra-precision polishing process is a step of performing polishing using abrasive grains that have a very small mean particle size of about 500 nm or less (for example, from about 10 nm to about 500 nm). The purpose of the ultra-precision polishing process is to perform further mirror polishing of the substrate (the glass plate) for improving the surface roughness. Similar to the above polishing processes, a material of the abrasive grains is appropriately selected depending on the material of the substrate (the glass plate). From the viewpoint of being able to obtain a smooth main surface of the substrate (the glass plate) with a small mean particle size, silica or colloidal silica is preferred, and colloidal silica is particularly preferred. It is preferred that the polishing pad used in the ultra-precision polishing process is a soft or ultra-soft polisher from the viewpoint of further mirror polishing. The polishing pad having the compression deformation amount and the 100% modulus described below is preferably used from the viewpoint of reducing an undulation and obtaining the predetermined spatial frequency in the present disclosure.

The local treatment process, which follows the ultra-precision polishing process as described above, is a process in which any convex parts in predetermined areas on the glass are locally machined based on machining conditions corresponding to the machining allowance set by the arithmetic processing. By performing the local treatment process, the flatness of the main surface of the substrate (the glass plate) is controlled below a predetermined reference value.

Exemplary methods of the local treatment process of the substrate (the glass plate) include magnetorheological finishing (MRF), in which magnetic abrasive slurry having abrasive grains contained in magnetic fluid with iron is brought into contact with a substrate. Other than MRF, gas cluster ion beam etching (GCIB) or plasma etching can be used as the local treatment process.

The finishing polishing process is performed for the purpose of removing surface roughness or a deteriorated layer on the main surface of the substrate (the glass plate) when such surface roughness or deteriorated layer is caused by the local treatment process. By using a polishing pad with the predetermined amount of compressive deformation and the 100% modulus value in the finishing polishing process, the amplitude in the range of a predetermined spatial frequency on the main surface of the glass body 400 (and the substrate formed therefrom) can be adjusted. The polishing amount for adjusting the amplitude is preferably 0.05 μm to 1 μm, more preferably 0.1 μm to 0.8 μm.

As a method for the finishing polishing process, a polishing method that maintains the flatness obtained by the local treatment process and still improves the surface roughness is preferred. Exemplary methods include a precision polishing method in which polishing is performed with a polishing liquid under a state in which the main surface of the substrate is in contact with a surface of a polishing tool such as the polishing pad or a noncontact polishing method in which the main surface of the substrate and a surface of a polishing tool are not brought into direct contact with each other and polishing is performed by the action of a treatment fluid therebetween (for example, float polishing method or elastic emission machining (EEM) method), and the like.

The polishing pad used in the above-disclosed polishing processes includes a base material formed of a nonwoven fabric, a resin film of a PET resin, or the like, and a nap layer formed on the base material and formed of a foamed resin having pores in the surface thereof. A buffer layer may be included between the base material and the nap layer. The buffer layer is arranged for the purpose of adjusting a compression deformation amount of the entire polishing pad and is preferably a foamed resin. It is preferred that the polishing pad has a compression deformation amount of about 360 μm or less. The compression deformation amount is more preferably about 320 μm or less. It is preferred that the resin forming the nap layer has a 100% modulus of about 3 MPa or more and about 14 MPa or less. The 100% modulus is more preferably about 10 MPa or less. Measurement methods of the compression deformation amount and the 100% modulus comprise the methods disclosed in U.S. Pat. No. 9,778,209 B.

By using a polishing pad with a predetermined amount of compressive deformation and a 100% modulus value in the above-described ultra-precision polishing process and/or the finishing polishing process, the amplitude in the range of a predetermined spatial frequency on the main surface of the glass body 400 (and the substrate formed therefrom) can be adjusted.

### Substrate With Multilayer Reflective Film

FIG. 6 shows a schematic sectional view illustrating a substrate with a multilayer reflective film according to the embodiments of the present disclosure. The substrate with a multilayer reflective film, collectively 600, comprises the mask blank substrate 601 (which may be mask blank substrate 501 and formed from glass body 400, as disclosed above) and a multilayer reflective film 602 on a main surface of the mask blank substrate 601 on which the transfer pattern is to be formed. The substrate with a multilayer reflective film 600 may further comprise a protective film 603 on the multilayer reflective film 602.

The material for the multilayer reflective film 602 is not particularly limited as long as it reflects EUV light (the reflective multilayer film 602 generally has a reflectance of not less than about 65% by itself and has an upper reflectance limit of about 73%). In general, such a multilayer reflective film 602 may comprise one or more thin films made of a material with a high refractive index (high refractive index layers) and one or more thin films made of a material with a low refractive index (low refractive index layers) alternately layered for about 40 to about 60 periods.

For example, it is preferable that the multilayer reflective film 602 for EUV light with a wavelength of 13 nm to 14 nm is a Mo/Si periodic multilayer film having Si films and Mo films alternately layered for about 40 periods. As other multilayer reflective films for use in the region of EUV light, a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, and a Si/Ru/Mo/Ru periodic multilayer film are available.

The protective film 603 may be formed on the multilayer reflective film 602 or in contact with a surface of the multilayer reflective film 602 in order to protect the multilayer reflective film 602 from dry etching and cleaning. A material of the protective film 603 may be selected from, for example, materials such as a metal single substance of Ru, Ru alloys containing at least one metal selected from titanium (Ti), niobium (Nb), rhodium (Rh), molybdenum (Mo), zirconium (Zr), yttrium (Y), boron (B), lanthanum (La), cobalt (Co) and rhenium (Rc) in Ru, and materials containing nitrogen in the Ru or the Ru alloys.

A back-side conductive film may be formed on a main surface of the substrate 601 of the substrate with a multilayer reflective film 600, which is opposite to the main surface contacting the multilayer reflective film 602, for the purpose of contact with an electrostatic chuck. The substrate with a multilayer reflective film 600, according to the present disclosure, includes the structure of the substrate with a multilayer reflective film 600 having the back-side conductive film on a main surface of the substrate 601 on the side the multilayer reflective film 602 is not formed. The electrical property (sheet resistance) required for the back-surface conductive film is typically not more than 100Ω/□. The method of forming the back-side conductive film is common knowledge in the art. The back-side conductive film may be formed by, for example, magnetron sputtering or ion beam sputtering method by using a target of metal or an alloy of Cr, Ta, or the like.

### Reflective Mask Blank

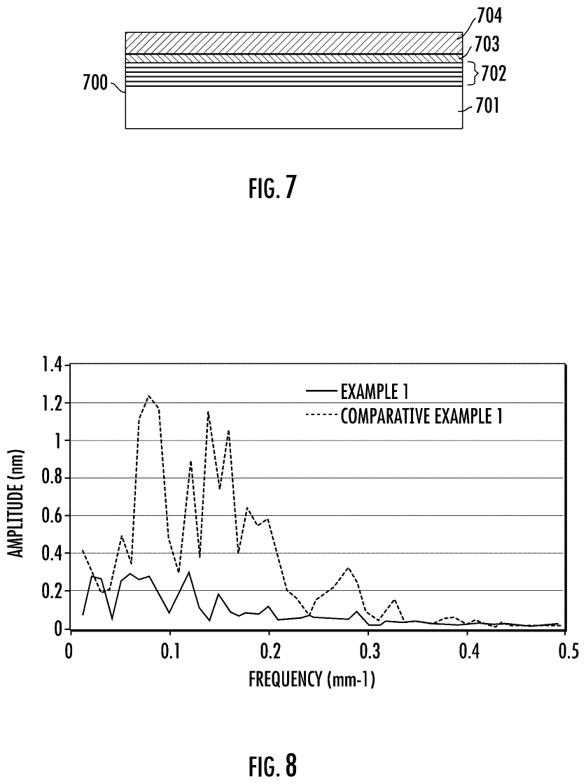

FIG. 7 shows a schematic sectional view illustrating an exemplary reflective mask blank 700 according to the embodiments of the present disclosure. The reflective mask blank 700 comprises mask blank substrate 701 (which may be mask blank substrate 501 and formed from glass body 400, as disclosed above), multilayer reflective film 702 on the mask blank substrate 701, and an absorber film 704 on or above the multilayer reflective film 702. The reflective mask blank 700 may include a protective film 703 between the multilayer reflective film 702 and the absorber film 704. The reflective mask blank 700 can be produced by forming the absorber film 704 on the above described substrate with the multilayer reflective film 600.

The material of the absorber film 704 is not particularly limited as long as it has a function of absorbing EUV light, can be processed by etching, etc. (preferably by dry etching with chlorine (Cl) based gas and/or fluorine (F) based gas), and has a high etching selectivity with respect to the protective film 703. As those having such functions, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), alloys containing two or more metals, or compounds thereof can be preferably used. The compound may contain oxygen (O), nitrogen (N), carbon (C) and/or boron (B) in the above metal or alloy.

A back-side conductive film may be formed on a main surface of the substrate 701 of the reflective mask blank 700, which is opposite to the main surface contacting the multilayer reflective film 702, for the purpose of contact with an electrostatic chuck. The reflective mask blank 700 according to the present disclosure includes the structure of reflective mask blank 700 having the back-side conductive film on a main surface on the side the multilayer reflective film 702 is not formed. A detailed explanation of the back-surface conductive film is described above.

A reflective mask can be prepared by patterning the absorber film 704 of the reflective mask blank. A lithography process can be used for patterning the absorber film 704. The reflective mask can be used for EUV lithography for forming integrated circuit patterns of semiconductor devices.

### EXAMPLES OF ASPECTS OF EMBODIMENTS

Embodiments of some aspects of the present disclosure are described in more detail below with reference to exemplary examples. The various embodiments of the present disclosure are not limited to the following exemplary examples.

### Example 1

A mask blank substrate of Example 1 was prepared by performing the steps 110, 120, 130, 140, 150 and 160 to prepare a mask blank substrate 501. The step 160 in Example 1 included the specific polishing processes described below. Specifically, the mask blank substrate was prepared under the following conditions.
<Step 110>

Soot particles 260 of SiO₂—TiO₂ was produced by introducing a vaporous steam of a mixture of silica and titania precursors into flame in burners 254.
<Step 120>

A molded body 360 was formed with the soot particles 260 that were deposited into a mold 300 and pressed in a pressing process.
<Step 130>

The consolidation step was performed for the molded body 360 to produce a consolidated molded body 370 in a consolidation furnace.
<Step 140>

The consolidated molded body 370 was melted in a rectangular mold to form a rectangular glass body 380.
<Step 150>

The glass body 380 was annealed to relax internal stress in the glass body 380 to form an annealed glass body 390 under the following conditions.
<Step 160>

Glass plates were prepared by slicing the annealed glass body 390 into pieces to form glass plates.

A glass plate sized to be 152.4 mm×152.4 mm and having a thickness of 6.35 mm was prepared for producing a mask blank substrate 501 of Example 1. After preparation of the glass plate, a rough polishing process, a precision polishing process, an ultra-precision polishing process, a local treatment process, and a finishing polishing process were performed on the glass plate, as follows.

### <<Rough Polishing Process>>

The glass plate was subjected to an end surface chamfering treatment and a grinding treatment using a double side lapping apparatus. After the treatments, the glass plate was set in a double side polisher, and the rough polishing process was performed under the following polishing conditions. A treatment load and polishing time were appropriately adjusted.

Polishing liquid: Aqueous solution containing cerium oxide (average particle size 2 to 3 μm).

Polishing Pad: Hard polisher (an urethane pad).

After the rough polishing process, the glass substrate was immersed in a cleaning bath (ultrasound application) and cleaned in order to remove abrasive grains attached to the glass plate.

### <<Precision Polishing Process>>

Using a double side polisher, the precision polishing process was performed on the glass plate after the rough polishing process, under the following polishing conditions. A treatment load and polishing time were appropriately adjusted.

Polishing liquid: Aqueous solution containing cerium oxide (average particle size: 1 μm).

Polishing Pad: Soft Polisher (Swede Type).

After the precision polishing process, the glass plate was immersed in a cleaning bath (ultrasound application) and cleaned in order to remove abrasive grains attached to the glass substrate.

### <<Ultra-Precision Polishing Process>>

The ultra-precision polishing process was performed on the glass plate after the precision polishing process using the double side polisher described above, under the following polishing conditions. A treatment load and polishing time were appropriately adjusted.

Polishing liquid: Alkaline aqueous solution containing colloidal silica (pH: 10.5).

Polishing Pad: Soft Polisher (Swede Type).

After the ultra-precision polishing process, the glass substrate was cleaned in a low concentration aqueous solution of hydrofluosilicic acid in order to remove abrasive grains (colloidal silica) attached to the glass plate, and rinsing was performed with pure water.

### <<Local Treatment Process>>

The local treatment process performed for the glass plate after the ultra-precision polishing process, as follows.

The surface shapes (surface state, flatness) of areas of 148 mm×148 mm at the top and bottom sides of the glass plate and TTV (variation in thickness) were measured with a wavelength shift interferometer using a laser wavelength modulation. As a result, the flatness of each of the top and bottom sides of the glass plate were 290 nm (convex shape). The results of measuring the surface shape (flatness) of the surfaces of the glass plate were saved in a computer as height information with respect to a reference surface provided for each measuring point. The height information was compared with a reference value of 50 nm (convex shape) of the flatness of the top surface and was compared with a reference value of 50 nm of the flatness of the bottom surface, which were needed for the glass plate. A difference (a required amount of removal) between the height information and each reference value was computed by the computer.

Then, the processing conditions for the local surface processing according to the required amount of removal were set for each area of a processing spot in the surface of the glass plate. A dummy glass plate was spot-processed in advance in the same manner as in the actual processing without being moved for a given period of time, the shape of the dummy glass plate was measured with the same measuring device as used to measure the shapes of the top and bottom surfaces, and the volume of spot processing per unit time was calculated. Then, the scanning speed for raster scanning of the glass plate was decided based on the required amount of removal obtained from the spot information and the information on the surface shape of the glass plate.

The surface shape was adjusted by performing a local surface treatment by magneto rheological finishing (MRF) according to the processing conditions to be set, using a substrate finishing device with magnetic fluid, in such a way that the flatness of each of the top and bottom sides of the glass plate would not become more than the reference value described above. It is noted that the magnetic viscoelastic fluid used for this treatment contained an iron component, and the polishing slurry was an aqueous alkali solution containing abrasives (about 2 wt. %) of cerium oxide. Thereafter, the glass plate was immersed in a cleaning bath (temperature of about 25° C.) containing aqueous hydrochloric acid with a concentration of about 10% for about 10 minutes, and then rinsed with pure water and dried using isopropyl alcohol.

### <<Finishing Polishing Process>>

The finishing polishing process was performed for the glass plate after the local treatment process, as follows.

Both sides of the glass plate were polished with a double-side polishing apparatus under the polishing conditions to keep or improve surface shapes of the surfaces of the glass substrate. This finish polishing was performed under the following polishing conditions.

Working fluid: Aqueous alkaline solution (NaOH) containing abrasive (concentration: about 2 wt. %).

Abrasive: Colloidal silica, average particle size of about 70 nm.

Polishing Pad: Soft polisher with a base material (polyethylene terephthalate), and a buffer layer (a layer to control the amount of compressive deformation of the entire polishing pad) and a nap layer made of foamed resin with holes on the base material.

An amount of compressive deformation of the polishing pad was 240 μm, and a 100% modulus of the resin forming the nap layer was 7 MPa.

Polishing plate rotational speed: About 1 to 50 rpm

Processing pressure: About 0.1 to 10 kPa.

Polishing time: About 1 to 10 minutes.

Then, the glass plate was cleaned with an aqueous alkaline solution (NaOH).

Thus, the mask blank substrate 501 of Example 1 was manufactured by polishing and cleaning the glass plate.

The surface profile of a main surface, on which a transfer pattern is to be formed, of each of the mask blank substrates 501 was measured using a surface profile analysis apparatus (UltraFlat™ 200M (produced by Corning Tropel®), and then Power spectrum analysis was performed. Metro Pro ver. 8.0.1 (Zygo Corporation) was used for the power spectrum analysis. The measurement area was an inner area of a square with a side of 142 mm aligned to the center of the substrate 501 as a reference point.

As shown in FIG. 8, the power spectrum analysis of the mask blank substrate 501 in Example 1 showed that the shape of the main surface, on which the transfer pattern is to be formed, has an amplitude of 0.35 nm or less in the range of spatial frequencies from 0.05 mm⁻¹ to 0.2 mm⁻¹.

The flatness of the transfer pattern formation region (132 mm×132 mm) of the obtained mask blank substrate 501 was 28 nm.

When an area of 1 μm×1 μm in an arbitrary part of the transfer pattern formation region (132 mm×132 mm) of the obtained mask blank substrate 501 was measured by an atomic force microscope, the surface roughness was determined to have a root mean square roughness (Rms) of 0.065 nm.

### Example 2

The mask blank substrate 501 of Example 2 was prepared in the same manner as in Example 1 except that the amount of compression deformation of the polishing pad in the finishing polishing process and the 100% modulus of the nap layer were changed.

The amount of compressive deformation of the polishing pad for Example 2 was 350 μm, and the 100% modulus of the resin forming the nap layer was 3 MPa.

Power spectrum analysis of the mask blank substrate 501 of Example 2 was performed with the same manner as Example 1. As the result of Example 2, the shape of the main surface, on which the transfer pattern is to be formed, has an amplitude of 0.58 nm or less in the range of spatial frequencies from 0.05 mm⁻¹ to 0.2 mm⁻¹.

The flatness of the transfer pattern formation region (132 mm×132 mm) of the obtained mask blank substrate 501 of Example 2 was 35 nm.

When an area of 1 μm×1 μm in an arbitrary part of the transfer pattern formation area (132 mm×132 mm) of the mask blank substrate 501 of Example 2 was measured by an atomic force microscope, the surface roughness was determined to have a root mean square roughness (Rms) of 0.069 nm.

### Example 3

The mask blank substrate 501 of Example 3 was prepared in the same manner as in Example 1 except that the amount of compression deformation of the polishing pad in the finishing polishing process and the 100% modulus of the nap layer were changed.

The amount of compressive deformation of the polishing pad in Example 3 was 300 μm, and the 100% modulus of the resin forming the nap layer was 5 MPa.

Power spectrum analysis of the mask blank substrate 501 of Example 3 was performed with the same manner as Example 1. As the result of Example 3, the shape of the main surface, on which the transfer pattern is to be formed, has an amplitude of 0.45 nm or less in the range of spatial frequencies from 0.05 mm⁻¹ to 0.2 mm⁻¹.

The flatness of the transfer pattern formation region (132 mm×132 mm) of the obtained mask blank substrate 501 of Example 3 was 31 nm.

When an area of 1 μm×1 μm in an arbitrary part of the transfer pattern formation area (132 mm×132 mm) of the mask blank substrate 501 of Example 3 was measured by an atomic force microscope, the surface roughness was determined to have a root mean square roughness (Rms) of 0.071 nm.

Since Examples 1 to 3 have amplitudes of 0.6 nm or less in the range of spatial frequencies from 0.05 mm⁻¹ to 0.2 mm⁻¹ on the main surface of the substrate, it can be said that the pattern can be transferred to meet the requirement of overlay accuracy even when reflective masks that are manufactured with the reflective mask blanks with the substrates 501 of Examples 1 to 3 are used for exposure transfer to a resist film on semiconductor substrates using a next generation of high power EUV exposure equipment.

### Comparative Example 1

In Comparative Example 1, a mask blank substrate 501 of Comparative Example 1 with 152.4 mm×152.4 mm in size and 6.35 mm in thickness was prepared by the method described in U.S. Pat. No. 5,970,751.

More specifically, soot particles were produced by the same manner as Step 110 in Example 1 such that the mixture of a silica precursor and a titania precursor was delivered in vapor form to a flame to form SiO₂—TiO₂ soot particles. The soot particles were deposited in a cup and melted within a refractory furnace to form a solid body referred to as a boule of Comparative Example 1.

After preparation of the boule of Comparative Example 1, the boule was sliced and polished in the as Example 1. More specifically, the rough polishing process, the precision polishing process, the ultra-precision polishing process, the local treatment process, and the finishing polishing process were performed for polishing the sliced boule (a glass plate) of Comparative Example 1 in the same manner as in Example 1.

FIG. 8 shows the results of power spectrum analysis of the mask blank substrate 501 of Comparative Example 1. The power spectrum analysis was performed in the same manner as Example 1.

As shown in FIG. 8, the power spectrum analysis of the mask blank substrate 501 of Comparative Example 1 shows that the shape of the main surface, on which the transfer pattern is to be formed, has an amplitude of more than 0.6 nm in the range of spatial frequencies from 0.05 mm⁻¹ to 0.2 mm⁻¹.

The flatness of the transfer pattern formation region (132 mm×132 mm) of the obtained mask blank substrate 501 of Comparative Example 1 was 38 nm.

When an area of 1 μm×1 μm in an arbitrary part of the transfer pattern formation area (132 mm×132 mm) of the mask blank substrate 501 of Comparative Example 1 was measured by an atomic force microscope, the surface roughness was determined to have a root mean square roughness (Rms) of 0.068 nm.

It will be apparent to those skilled in the art that various modifications and variations can be made to embodiments of the present disclosure without departing from the spirit and scope of the disclosure. Thus, it is intended that the present disclosure cover such modifications and variations provided they come within the scope of the appended claims and their equivalents.

What is claimed is:

1. A method of forming a glass body, the method comprising:
pressing titania-doped silica soot to form a molded body;
consolidating the molded body by heating the molded body;
annealing the consolidated molded body; and
polishing at least one surface of the annealed molded body to form the glass body,
wherein, after the polishing, the at least one surface of the glass body has a waviness amplitude of about 0.60 nm or less in the spatial frequency range of 0.05 mm⁻¹ or more and 0.2 mm⁻¹ or less.

2. The method of claim 1, further comprising slicing the annealed molded body into at least one glass plate, the glass plate comprising a first main surface and a second main surface, and wherein the polishing at least one surface comprises polishing at least one of the first main surface and the second main surface to form the glass body.

3. The method of claim 2, wherein the polishing of the at least one surface of the glass plate comprises moving at least one of the glass plate and a polishing pad relative to each other, the polishing pad being formed of a foamed resin.

4. The method of claim 1, wherein the glass body comprises SiO₂—TiO₂ glass containing about 5 wt. % to about 10 wt. % TiO₂.

5. The method of claim 4, wherein a difference between a maximum concentration of TiO₂ and a minimum concentration of TiO₂ in the glass body is about 0.05 wt. % or less.

6. The method of claim 5, wherein pressing the titania-doped silica soot comprises pressing loose soot particles to form the molded body, the loose soot particles each have an average diameter from about 60 nm to about 140 nm.

7. The method of claim 1, wherein pressing the titania-doped silica soot comprises pressing loose soot particles to form the molded body, the loose soot particles each have an average diameter from about 60 nm to about 140 nm.

8. The method of claim 7, wherein the molded body is annealed at a maximum temperature from about 900° C. to about 1200° C.

9. The method of claim 1, wherein the molded body is annealed at a maximum temperature from about 900° C. to about 1200° C.

10. The method of claim 1, wherein the polishing of the at least one surface of the glass plate comprises moving at least one of the glass plate and the polishing pad relative to each other, the polishing pad being formed of a foamed resin.

11. The method of claim 1, wherein the glass body comprises SiO₂—TiO₂ glass and a difference between a maximum concentration of TiO₂ and a minimum concentration of TiO₂ in the glass body is about 0.05 wt. % or less.

12. A polished glass body comprising:
a first surface having a waviness amplitude of about 0.60 nm or less in the spatial frequency range of 0.05 mm⁻¹ or more and 0.2 mm⁻¹ or less,
wherein the polished glass body is a SiO₂—TiO₂ glass that contains about 5 wt. % to about 10 wt. % TiO₂.

13. The polished glass body of claim 12, wherein a difference between a maximum concentration of TiO₂ and a minimum concentration of TiO₂ in the polished glass body is about 0.05 wt. % or less.

14. The polished glass body of claim 13, wherein the polished glass body is a mask blank substrate of a reflective mask for EUV lithography.

15. The polished glass body of claim 12, wherein the polished glass body is a mask blank substrate of a reflective mask for EUV lithography.

16. The polished glass body of claim 12, wherein the polished glass body comprises a root mean square roughness (Rms) of less than about 0.13 nm.

17. The polished glass body of claim 16, wherein the root mean square roughness (Rms) is less than about 0.12 nm.

18. The polished glass body of claim 12, wherein the polished glass body comprises a flatness of about 0.1 μm or less.

19. The polished glass body of claim 18, wherein the flatness is about 0.05 μm or less.

20. The polished glass body of claim 12, wherein the waviness amplitude is about 0.45 nm or less.
